(19) United States
(12) Patent Application Publication
(10) Pub. No.: US 2007/0002994 A1
(43) Pub. Date: Jan. 4, 2007

(54) Clock jitter estimation apparatus, systems, and methods

(76) Inventors: Ofir Kanter, Haifa (IL); Eran Peleg, Akko (IL); Aharon El-Bahar, Haifa (IL)

Correspondence Address: SCHWEGMAN, LUNDBERG, WOESSNER & KLUTH, P.A., P.O. BOX 2938, MINNEAPOLIS, MN, 55402, US

(21) Appl. No.: 11/173,221

(22) Filed: Jun. 30, 2005

(51) Int. Cl. H03D 3/24

(52) U.S. Cl. 375/376

(57) ABSTRACT

Apparatus, systems, methods, and articles may operate to estimate an amount of jitter associated with a clock at an output of a digital phase-locked loop (DPLL), wherein the DPLL includes a phase frequency detector (PFD). The estimate may be made by sensing periods of timing coincidence between an up signal on a first output of the PFD and a down signal on a second output of the PFD. A pulse coincidence detector coupled to the PFD and a jitter estimation module coupled to the pulse coincidence detector may perform the estimate.

### TECHNICAL FIELD

Various embodiments described herein relate to digital communications generally, including apparatus, systems, and methods used to estimate amounts of jitter in a digital phase-locked loop.

### BACKGROUND INFORMATION

A modern digital or analog circuit may utilize the well-known phase-locked loop (PLL) or delay-locked loop (DLL) as a reference source in a clock tree. That is, the PLL or DLL, referred to collectively herein as a “digital phase-locked loop” (DPLL), may feed a clock sub-division and distribution system within the circuit. A downstream clock within the clock tree may be used to clock data between circuit elements or between circuits employed within a data communications system. The data may be successfully clocked into or clocked from the circuits when an edge of the downstream clock coincides with the data.

Conversely, jitter in the downstream clock may cause errors in the received data, especially when the received signal comprises analog data. A significant portion of cumulative phase jitter within the clock tree may derive from the DPLL. Thus, an amount of phase jitter associated with an output of the DPLL may be representative of the amount of phase jitter associated with the downstream clock.

Fast clock reference jitter analysis during production testing may be complex and time consuming. Jitter measurement may require off-chip test equipment including sampling oscilloscopes, spectrum analyzers and dedicated jitter measurement instruments. These instruments may be expensive to purchase and maintain, and test time for fast clock analysis may extend to several minutes.

### BRIEF DESCRIPTION OF THE DRAWINGS

FIG. 1 is a block diagram of an apparatus, a representative system, and a timing diagram according to various embodiments of the invention.

FIG. 2 is a flow diagram illustrating several methods according to various embodiments of the invention.

FIG. 3 is a block diagram of an article according to various embodiments of the invention.

### DETAILED DESCRIPTION

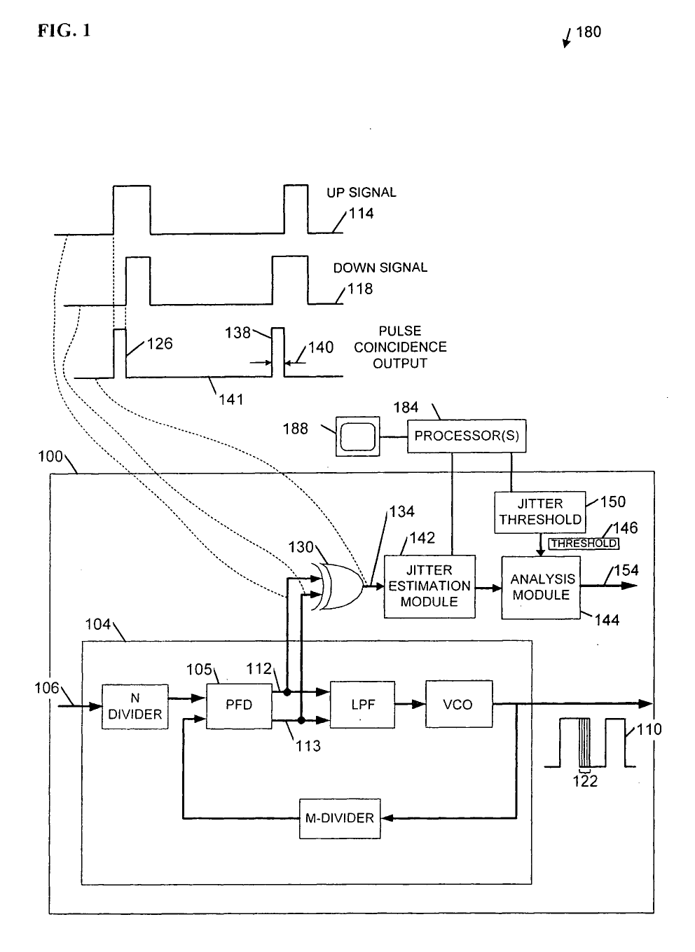

FIG. 1 comprises a block diagram of an apparatus 100 and a system 180 according to various embodiments of the invention. Some embodiments may utilize phase shifts sensed within a phased frequency detector (PFD)-type DPLL 104. A PFD 105 may evaluate a phase shift between (a) a reference clock (e.g., a crystal oscillator) at a DPLL input 106 and (b) a voltage-controlled oscillator (VCO) clock comprising a DPLL output clock 110. The PFD may output signal(s) corresponding to the phase shift between the reference clock and the VCO clock.

A pulse train may appear at each of two PFD outputs 112, 113. An “up” output signal 114 may appear at the PFD output 112 and a “down” output signal 118 may appear at the PFD output 113. The up output signal 114 may be generated to move the VCO output phase forward in time to match a leading reference clock phase. The down output signal 118 may operate to move the VCO output phase backward in time to match a lagging reference clock phase. Some embodiments of the invention may reverse these relationships such that the up output signal 114 moves the VCO output phase backward in time and the down output signal 118 moves the VCO output phase forward in time. A ratio between a pulse width of the up output signal 114 and a pulse width of the down output signal 118 may determine whether the VCO output phase moves backward or forward in time.

Since these PFD output signals represent a phase shift between the reference clock and the DPLL output clock 110, they may correlate to jitter 122 associated with the output clock 110. When the DPLL 104 is locked and experiences no jitter or phase shift, the up and down signals 114, 118 may be of similar width. They may both be open circuit, neither sinking nor sourcing current, or both signals may comprise narrow-width pulse trains.

Some embodiments of the invention may monitor a pulse width difference 126 between the PFD up output signal 114 and the down output signal 118. The embodiments may correlate the pulse width difference 126 to an amount of the jitter 122. One such embodiment may utilize a pulse coincidence detector 130 to perform an exclusive-OR (XOR) operation on the up and down signals 114, 118 to estimate the amount of the jitter 122. A DPLL 104 in lock and experiencing no jitter may yield a low logic level at an output 134 of the pulse coincidence detector 130. Conversely, a pulse 138 at output 134 of the pulse coincidence detector 130 may signify that the jitter 122 is present at the output 110. A width 140 of the XOR output pulse 138 may correspond to the amount of the jitter 122, exclusive of delay through the pulse coincidence detector 130. Some embodiments of the invention may use logic gates or devices other than an XOR gate to implement the pulse coincidence detector 130. Thus, subsequent examples herein using an XOR device may be alternatively implemented. A delayed-response OR gate may comprise one such alternative implementation.

The apparatus 100 may thus comprise the DPLL 104 including the PFD 105. The DPLL 104 may be used in a variety of circuits, including use as a clock to clock received data into a transceiver, for example. The apparatus 100 may also include the pulse coincidence detector 130 coupled to the PFD 105 to sense periods of timing coincidence between the up output signal 114 of the PFD 105 and the down output signal 118 of the PFD 105. In some embodiments the pulse coincidence detector 130 may comprise a dual-input exclusive-OR (XOR) module.

An average duty cycle of a pulse train 141 at the output 134 of the pulse coincidence detector 130 may comprise the estimate of the amount of the jitter 122 associated with the DPLL output clock 110. A jitter estimation module 142 coupled to the output 134 of the pulse coincidence detector 130 may estimate the amount of the jitter 122

The apparatus 100 may also include an analysis module 144 coupled to the jitter estimation module 142 to compare the amount of the jitter 122 associated with the DPLL output clock 110 to a programmable threshold value 146. A jitter threshold module 150 coupled to the analysis module 144 may set the programmable threshold value 146. An output 154 of the analysis module 144 may comprise a pass/fail indication of an acceptable amount of the jitter 122 in the DPLL output clock 110 in a production environment. Other outputs including analog and digital indications may be possible. One or more of the pulse coincidence detector 130, the jitter estimation module 142, the analysis module 144, and the jitter threshold module 150 may be located on the same die as the DPLL 104. These elements may comprise a built-in self-test capability, useful in production testing.

In another embodiment, a system 180 may include one or more of the apparatus 100, including a DPLL 104 with a PFD 105, a pulse coincidence detector 130, a jitter estimation module 142, an analysis module 144, and a jitter threshold module 150. The DPLL 104 may comprise a phase-locked loop of any type containing the PFD 105, including a delay-locked loop (DLL). An average duty cycle of a pulse train 141 at an output 134 of the pulse coincidence detector 130 may be proportional to an amount of jitter 122 associated with a DPLL output clock 110, including perhaps to an average amount of the jitter 122.

The system 180 may further include one or more processor(s) 184 coupled to the jitter estimation module 142 and a display 188 coupled to the processor(s) 184. The display 188 may comprise a cathode ray tube display or a solid-state display such as a liquid crystal display, a plasma display, or a light-emitting diode display, among others.

Any of the components previously described can be implemented in a number of ways, including embodiments in software. Thus, the apparatus 100; DPLL 104; PFD 105; DPLL input 106; DPLL output clock 110; PFD outputs 112, 113; PFD output signals 114, 118; jitter 122; pulse width difference 126; pulse coincidence detector 130; pulse coincidence detector output 134; pulse 138; pulse width 140; pulse train 141; jitter estimation module 142; analysis module 144; threshold value 146; jitter threshold module 150; analysis module output 154; system 180; processor(s) 184; and display 188 may all be characterized as “modules ” herein.

The modules may include hardware circuitry, single or multi-processor circuits, memory circuits, software program modules and objects, firmware, and combinations thereof, as desired by the architect of the apparatus 100 and system 180 and as appropriate for particular implementations of various embodiments.

It should also be understood that the apparatus and systems of various embodiments can be used in applications other than estimating output jitter associated with a PFD-type DPLL by analyzing pulse coincidence between a PFD up output signal and a PFD down output signal. Thus, various embodiments of the invention are not to be so limited. The illustrations of apparatus 100 and system 180 are intended to provide a general understanding of the structure of various embodiments. They are not intended to serve as a complete description of all the elements and features of apparatus and systems that might make use of the structures described herein.

Applications that may include the novel apparatus and systems of various embodiments include electronic circuitry used in high-speed computers, communication and signal processing circuitry, modems, single or multi-processor modules, single or multiple embedded processors, data switches, and application-specific modules, including multilayer, multi-chip modules. Such apparatus and systems may further be included as sub-components within a variety of electronic systems, such as televisions, cellular telephones, personal computers, workstations, radios, video players, audio players (e.g., mp3 players), vehicles, and others. Some embodiments may include a number of methods.

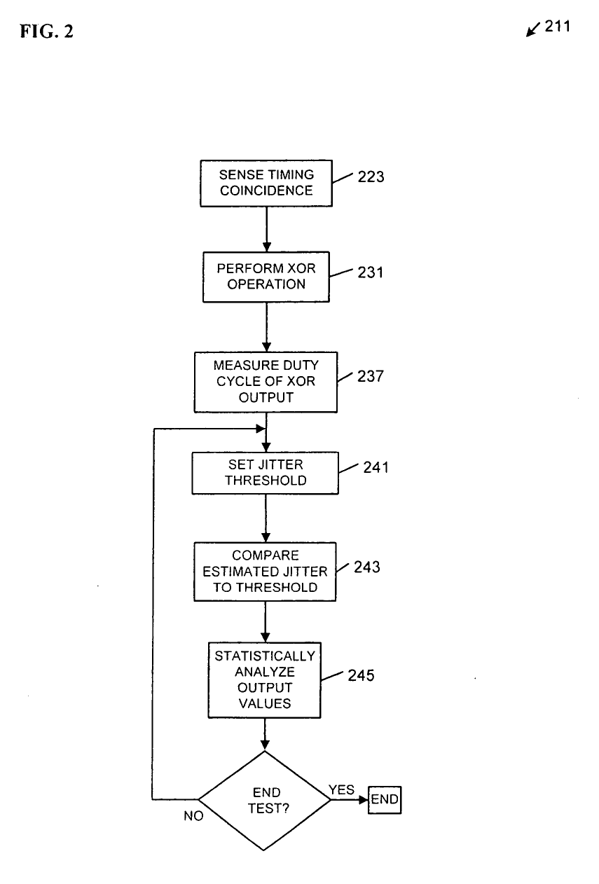

FIG. 2 is a flow diagram illustrating several methods according to various embodiments of the invention. The method 211 may include estimating an amount of jitter associated with a clock at an output of a DPLL, wherein the DPLL includes a PFD. The DPLL may comprise various designs containing the PFD, including a delay-locked loop. The amount of jitter may be inversely proportional to the periods of timing coincidence between a PFD up output signal and a PFD down output signal.

The method 211 may begin at block 223 with sensing periods of timing coincidence between an up signal on a first output of the PFD and a down signal on a second output of the PFD. The periods of coincidence may be sensed using a pulse coincidence detector coupled to the PFD and a jitter estimation module coupled to the pulse coincidence detector.

The method 211 may include performing an exclusive-OR (XOR) operation on the PFD LIP output signal and on the PFD down output signal using an XOR module to sense the periods of timing coincidence, at block 231. An average duty cycle of a pulse train at the output of the XOR module may comprise the estimate of the amount of jitter associated with the DPLL output clock. The method 211 may thus include measuring the average duty cycle of the pulse train at the output of the XOR module using the jitter estimation module, at block 237. Measures of the jitter estimate other than the average duty cycle of the pulse train at the output of the XOR module may be derived.

The method 211 may continue with setting a programmable threshold value of estimated jitter using a jitter threshold module coupled to an analysis module, at block 241. The estimated amount of jitter associated with the DPLL output clock may be compared to the programmable threshold value using the analysis module, at block 243. An output of the analysis module may comprise an analog signal representation of the estimated amount of jitter or a digital signal estimate, including a pass/fail indication. High and low limits of a range of jitter associated with the DPLL may be determined by running several test iterations, each with a different threshold configuration. The method 211 may conclude with performing a statistical analysis of a plurality of analysis module output values to determine a level of acceptability of the DPLL in a production environment, at block 245.

It may be possible to execute the activities described herein in an order other than the order described. And, various activities described with respect to the methods identified herein can be executed in repetitive, serial, or parallel fashion. Information including parameters, commands, operands, and other data can be sent and received in the form of one or more carrier waves.

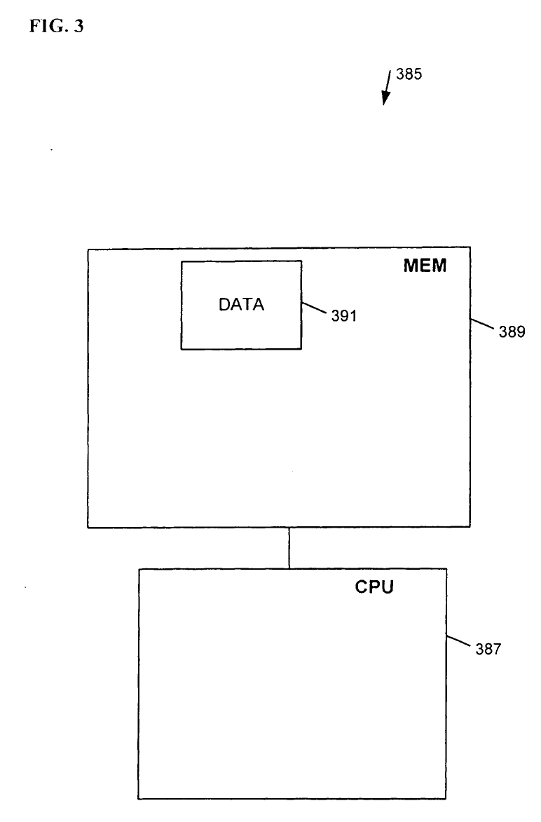

One of ordinary skill in the art will understand the manner in which a software program can be launched from a computer-readable medium in a computer-based system to execute the functions defined in the software program. Various programming languages that may be employed to create one or more software programs designed to implement and perform the methods disclosed herein. The programs may be structured in an object-orientated format using an object-oriented language such as Java or C++. Alternatively, the programs can be structured in a procedure-orientated format using a procedural language, such as assembly or C. The software components may communicate using a number of mechanisms well known to those skilled in the art, such as application program interfaces or inter-process communication techniques, including remote procedure calls. The teachings of various embodiments are not limited to any particular programming language or environment. Thus, other embodiments may be realized, as discussed regarding FIG. 3 below.

FIG. 3 is a block diagram of an article 385 according to various embodiments of the invention. Examples of such embodiments may comprise a computer, a memory system, a magnetic or optical disk, some other storage device, or any type of electronic device or system. The article 385 may include one or more processor(s) 387 coupled to a machine-accessible medium such as a memory 389 (e.g., a memory including electrical, optical, or electromagnetic elements). The medium may contain associated information 391 (e.g., computer program instructions, data, or both) which, when accessed, results in a machine (e.g., the processor(s) 387) estimating an amount of jitter associated with a clock at an output of a DPLL using a pulse coincidence detector, as previously described.

Other activities may include comparing the estimated amount of jitter associated with the DPLL output clock to a programmable threshold value using an analysis module coupled to the jitter estimation module. An analysis module output may comprise a pass/fail indication of the estimated amount of jitter associated with the DPLL output clock in a production environment, among other indications.

Implementing the apparatus, systems, and methods disclosed herein may provide a quick and economical means to estimate jitter associated with a DPLL device under test (DUT) in a production environment without the use of jitter analysis tools external to the DUT.

The accompanying drawings that form a part hereof show, by way of illustration and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein individually or collectively by the term “invention ” merely for convenience and without intending to voluntarily limit the scope of this application to any single invention or inventive concept, if more than one is in fact disclosed. Thus, although specific embodiments have been illustrated and described herein, any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted to require more features than are expressly recited in each claim. Rather, inventive subject matter may be found in less than all features of a single disclosed embodiment. Thus the following claims are hereby incorporated into the Detailed Description, with each claim standing on its own as a separate embodiment.

What is claimed is:

1. An apparatus, including:
a digital phase-locked loop (DPLL) including a phase frequency detector (PFD);
a pulse coincidence detector coupled to the PFD to sense periods of timing coincidence between an up signal on a first output of the PFD and a down signal on a second output of the PFD; and
a jitter estimation module coupled to an output of the coincidence detector to estimate an amount of jitter associated with a clock at a DPLL output.

2. The apparatus of claim 1, wherein the DPLL output clock operates to clock received data in a transceiver.

3. The apparatus of claim 1, wherein the pulse coincidence detector comprises a dual-input exclusive-OR (XOR) module.

4. The apparatus of claim 1, wherein an average duty cycle of a pulse train at an output of the pulse coincidence detector comprises the estimate of the amount of jitter associated with the DPLL output clock.

5. The apparatus of claim 1, further including:
an analysis module coupled to the jitter estimation module to compare the amount of jitter associated with the DPLL output clock to a programmable threshold value.

6. The apparatus of claim 5, further including:
a jitter threshold module coupled to the analysis module to set the programmable threshold value.

7. The apparatus of claim 6, wherein at least one of the pulse coincidence detector, the jitter estimation module, the analysis module, and the jitter threshold module is located on the same die as the DPLL.

8. The apparatus of claim 5, wherein an output of the analysis module comprises a pass/fail indication of an acceptable amount of jitter in the DPLL output clock in a production environment.

9. A system, including:
a digital phase-locked loop (DPLL) including a phase frequency detector (PFD);
a pulse coincidence detector coupled to the PFD to sense periods of timing coincidence between an up signal on a first output of the PFD and a down signal on a second output of the PFD; and
a jitter estimation module coupled to an output of the pulse coincidence detector to estimate an amount of jitter associated with an output of the DPLL;
a processor coupled to the jitter estimation module; and
a display coupled to the processor.

10. The system of claim 9, further including:
an analysis module coupled to the jitter estimation module to compare the amount of jitter associated with the DPLL output clock to a programmable threshold value.

11. The system of claim 10, wherein the DPLL comprises a delay-locked loop (DLL).

12. The system of claim 9, wherein an average duty cycle of a pulse train at the output of the pulse coincidence detector is proportional to an average amount of jitter associated with the DPLL output clock.

13. A method, including:
estimating an amount of jitter associated with a clock at an output of a digital phase-locked loop (DPLL), wherein the DPLL includes a phase frequency detector (PFD); and
sensing periods of timing coincidence between an up signal on a first output of the PFD and a down signal on a second output of the PFD using a pulse coincidence detector coupled to the PFD and a jitter estimation module coupled to the pulse coincidence detector.

14. The method of claim 13, wherein the amount of jitter associated with the DPLL output clock is inversely proportional to the periods of timing coincidence between the PFD up output signal and the PFD down output signal.

15. The method of claim 13, further including:
performing an exclusive-OR (XOR) operation on the PFD up output signal and on the PFD down output signal using an XOR module to sense the periods of timing coincidence.

16. The method of claim 15, wherein an average duty cycle of a pulse train at the output of the XOR module comprises the estimate of the amount of jitter associated with the DPLL output clock.

17. The method of claim 16, further including:
measuring the average duty cycle of the pulse train at the output of the XOR module using the jitter estimation module.

18. The method of claim 13, further including:
comparing the estimated amount of jitter associated with the DPLL output clock to a programmable threshold value using an analysis module coupled to the jitter estimation module.

19. The method of claim 18, further including:
setting the programmable threshold value using a jitter threshold module coupled to the analysis module.

20. The method of claim 19, wherein an output of the analysis module comprises at least one of an analog signal representation of the estimated amount of jitter and a digital signal estimate.

21. The method of claim 18, further including:
performing a statistical analysis of a plurality of analysis module output values to determine a level of acceptability of the DPLL in a production environment.

22. The method of claim 13, wherein the DPLL comprises a delay-locked loop (DLL).

23. An article including a machine-accessible medium having associated information, wherein the information, when accessed, results in a machine performing:
estimating an amount of jitter associated with a clock at an output of a digital phase-locked loop (DPLL), wherein the DPLL includes a phase frequency detector (PFD); and
sensing periods of timing coincidence between an up signal on a first output of the PFD and a down signal on a second output of the PFD using a pulse coincidence detector coupled to the PFD and a jitter estimation module coupled to the pulse coincidence detector.

24. The article of claim 23, wherein the information, when accessed, results in a machine performing:
comparing the estimated amount of jitter associated with the DPLL output clock to a programmable threshold value using an analysis module coupled to the jitter estimation module.

25. The article of claim 23, wherein an analysis module output comprises a pass/fail indication of the estimated amount of jitter associated with the DPLL output clock in a production environment.
